(19) United States
(12) Patent Application Publication
(10) Pub. No.: US 2026/0047183 A1
(43) Pub. Date: Feb. 12, 2026

(54) SEMICONDUCTOR DEVICE

(71) Applicant: DENSO CORPORATION, Kariya-city (JP)

(72) Inventors: Hiroto SUGIURA, Kariya-city (JP); Koichi MURAKAWA, Kariya-city (JP); Masakiyo SUMITOMO, Kariya-city (JP)

(21) Appl. No.: 19/312,925

(22) Filed: Aug. 28, 2025

Related U.S. Application Data
(63) Continuation of application No. PCT/JP2024/008771, filed on Mar. 7, 2024.

(30) Foreign Application Priority Data
Mar. 8, 2023 (JP) 2023-035962

(51) Int. Cl. H10D 84/00; H10D 62/10

(52) U.S. Cl. CPC H10D 84/161; H10D 62/127

(57) ABSTRACT

An IGBT region has a first region located adjacent to a FWD region and a second region located opposite to the FWD region through the first region. The first region is formed in a state where an emitter region is sparser than the second region and where a contact region is sparser than the second region. A region from an end of the FWD region adjacent to the IGBT region, including the first region, where the contact region is sparser than the second region is dimensioned within 2.2 times a thickness of a semiconductor substrate.

### CROSS REFERENCE TO RELATED APPLICATIONS

The present application is a continuation application of International Patent Application No. PCT/JP2024/008771 filed on Mar. 7, 2024, which designated the U.S. and claims the benefit of priority from Japanese Patent Application No. 2023-035962, filed on Mar. 8, 2023. The entire disclosures of all of the above applications are incorporated herein by reference.

### TECHNICAL FIELD

The present disclosure relates to a semiconductor device having an insulated gate bipolar transistor (IGBT) region in which an IGBT element is formed and a freewheeling diode (FWD) region in which an FWD element is formed.

### BACKGROUND

A semiconductor device has a reverse-conducting IGBT (RC-IGBT) in which an IGBT element and an FWD element are formed on a semiconductor substrate as a switching element of an inverter or the like.

### SUMMARY

According to one aspect of the present disclosure, a semiconductor device includes a semiconductor substrate and a trench gate structure. An IGBT region having an IGBT element and an FWD region having an FWD element are formed in the semiconductor substrate. The semiconductor substrate includes: a drift layer of a first conductivity type; a base layer of a second conductivity type formed on the drift layer; a collector layer of a second conductivity type formed opposite to the base layer through the drift layer in the IGBT region; and a cathode layer of a first conductivity type formed opposite to the base layer through the drift layer in the FWD region. The semiconductor substrate has: one surface adjacent to the base layer; and the other surface adjacent to the collector layer and cathode layer. The trench gate structure is formed in the IGBT region to have a gate insulating film on a wall surface of a trench and a gate electrode formed on the gate insulating film. The trench penetrates the base layer to reach the drift layer and extends in a surface direction of the semiconductor substrate as a longitudinal direction. An emitter region of a first conductivity type is formed in a surface layer of the base layer in the IGBT region to be in contact with the trench. A contact region of a second conductivity type is formed in a surface layer of the base layer in the IGBT region, different from the emitter region, to have a higher impurity concentration than the base layer. A first electrode is disposed on the one surface of the semiconductor substrate and electrically connected to the emitter region and the contact region. A second electrode is disposed on the other surface of the semiconductor substrate and electrically connected to the collector layer and the cathode layer. The IGBT region has a first region located adjacent to the FWD region and a second region located opposite to the FWD region through the first region. The first region is formed in a state where the emitter region is sparser than the second region, and where the contact region is sparser than the second region. A region from an end of the FWD region adjacent to the IGBT region, including the first region, where the contact region is sparser than the second region may be dimensioned within 2.2 times a thickness of the semiconductor substrate.

### BRIEF DESCRIPTION OF THE DRAWINGS

FIG. 1 is a plan view of a semiconductor device according to a first embodiment.

FIG. 2 is a cross-sectional view taken along line II-II in FIG. 1.

FIG. 3 is a cross-sectional view taken along line III-III in FIG. 1.

FIG. 4 is a plan view illustrating a semiconductor substrate of the semiconductor device.

FIG. 5 is a graph showing a relationship between a switching-on loss of an IGBT element and a width of a first region relative to a thickness of the semiconductor substrate.

FIG. 6 is a graph showing a relationship between a ratio of the maximum current density and a ratio of the first region to the entire IGBT region.

FIG. 7 is a cross-sectional view of a semiconductor device according to another embodiment.

### DETAILED DESCRIPTION

A semiconductor device has a reverse-conducting IGBT (RC-IGBT) in which an IGBT element and an FWD element are formed on a common semiconductor substrate as a switching element of an inverter or the like.

Specifically, in a semiconductor device, a base layer is formed in a surface layer of a semiconductor substrate that constitutes an n-type drift layer, and a trench gate structure is formed to penetrate the base layer. A surface of the semiconductor substrate adjacent to the base layer is defined as one surface, and another surface of the semiconductor substrate opposite to the one surface is defined as the other surface. A p-type collector layer and an n-type cathode layer are formed on the other surface of the semiconductor substrate. In the semiconductor device, a region on the other surface of the semiconductor substrate where the collector layer is formed is defined as an IGBT region and a boundary region, and another region where the cathode layer is formed is defined as an FWD region. The boundary region is formed between the IGBT region and the FWD region.

In the IGBT region, an n+ type emitter region having a higher impurity concentration than the drift layer and a p+ type contact region having a higher impurity concentration than the base layer are formed in a surface layer of the base layer. In the boundary region, a contact region is formed in the surface layer of the base layer, similar to the IGBT region. However, the contact region in the boundary region is formed sparser than the contact region in the IGBT region. In the semiconductor device, no emitter region is formed in the boundary region.

An upper electrode electrically connected to the emitter region and the contact region is formed on the one surface of the semiconductor substrate, and a lower electrode electrically connected to the collector layer and the cathode layer is formed on the other surface of the semiconductor substrate.

In the semiconductor device, the amount of holes injected from the high-concentration contact region toward the cathode layer during recovery when the IGBT element is switched from an off state to an on state can be reduced, compared to a case where no boundary region is formed. Therefore, the maximum reverse current Irr can be reduced, and the recovery loss Err can be restricted from increasing.

However, in the semiconductor device, due to the boundary region where the emitter region is not formed, if the boundary region is made too large, the maximum current density when the IGBT element is in the on state increases, which may result in a decrease in the short-circuit resistance.

The present disclosure provides a semiconductor device to suppress a decrease in short-circuit resistance.

According to one aspect of the present disclosure, an IGBT region having an IGBT element and an FWD region having an FWD element are formed on a common semiconductor substrate of a semiconductor device. The semiconductor substrate includes: a drift layer of a first conductivity type; a base layer of a second conductivity type formed on the drift layer; a collector layer of a second conductivity type formed on the drift layer opposite to the base layer in the IGBT region; and a cathode layer of a first conductivity type formed on the drift layer opposite to the base layer in the FWD region. The semiconductor substrate has one surface adjacent to the base layer and the other surface adjacent to the collector layer and cathode layer. Trench gate structures are formed in the IGBT region. The trench penetrates the base layer to reach the drift layer and extends in a surface direction of the semiconductor substrate as a longitudinal direction. A gate insulating film is formed on a wall surface of the trench, and a gate electrode is formed on the gate insulating film. An emitter region of a first conductivity type is formed in a surface layer of the base layer in the IGBT region to be in contact with the trench. A contact region of a second conductivity type is formed in a surface layer of the base layer in the IGBT region, different from the emitter region, to have a higher impurity concentration than the base layer. A first electrode is disposed on the one surface of the semiconductor substrate and electrically connected to the emitter region and the contact region. A second electrode is disposed on the other surface of the semiconductor substrate and electrically connected to the collector layer and the cathode layer. The IGBT region has a first region located adjacent to the FWD region and a second region located opposite to the FWD region through the first region. The first region is formed in a state where the emitter region is sparser than the second region, and where the contact region is sparser than the second region. A region from an end of the FWD region adjacent to the IGBT region, including the first region, where the contact region is sparser than the second region is dimensioned within 2.2 times a thickness of the semiconductor substrate.

Accordingly, the region from the end of the FWD region, including the first region, where the contact region is sparser than the second region is set within 2.2 times the thickness of the semiconductor substrate. The first region has the emitter region formed therein and also functions as the IGBT element. As a result, in this semiconductor device, while reducing the recovery loss Err and the switching-on loss Eon, it is possible to suppress an increase in the maximum current density, compared to a case where the first region is a boundary region in which no emitter region is formed. Therefore, in this semiconductor device, it is possible to suppress a decrease in short-circuit withstand capability while reducing the recovery loss Err and the switching-on loss Eon.

Hereinafter, embodiments of the present disclosure will be described with reference to the drawings. In each embodiment described below, same or equivalent parts are designated with the same reference numerals.

### First Embodiment

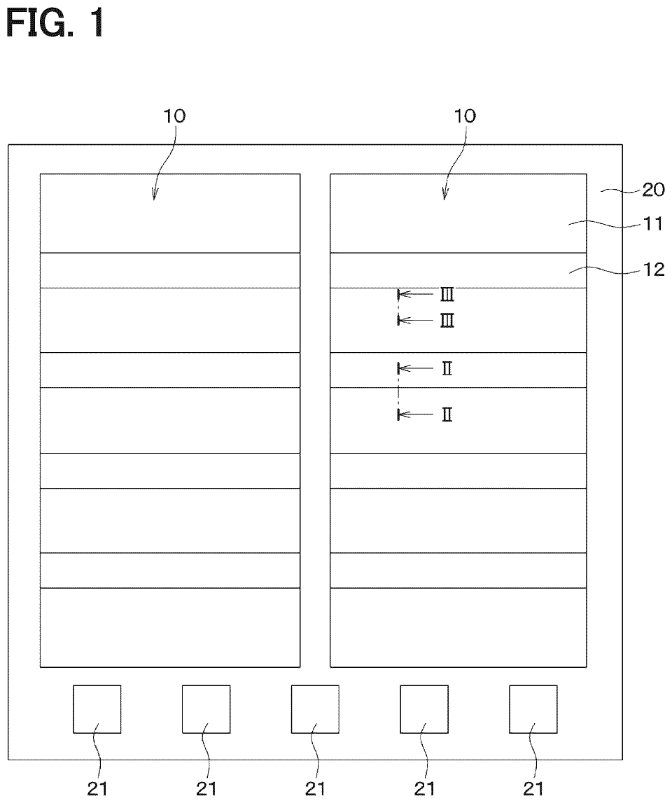

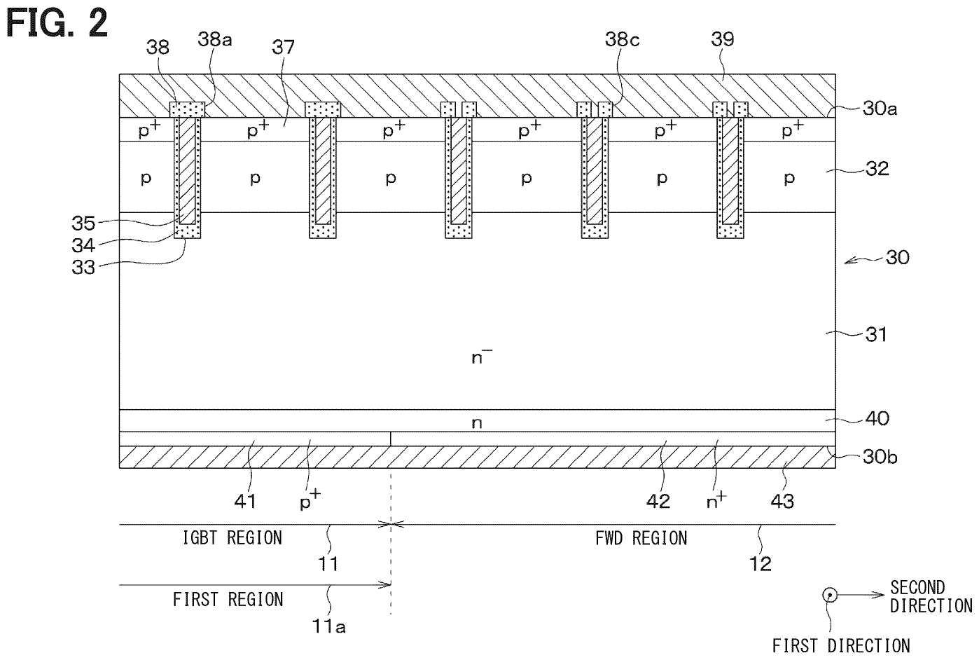

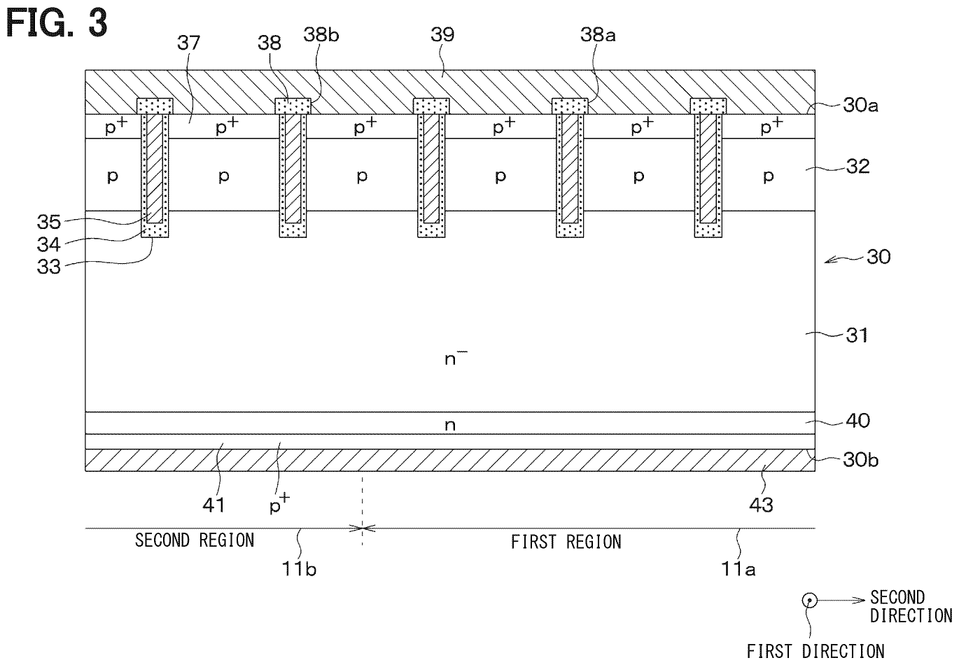

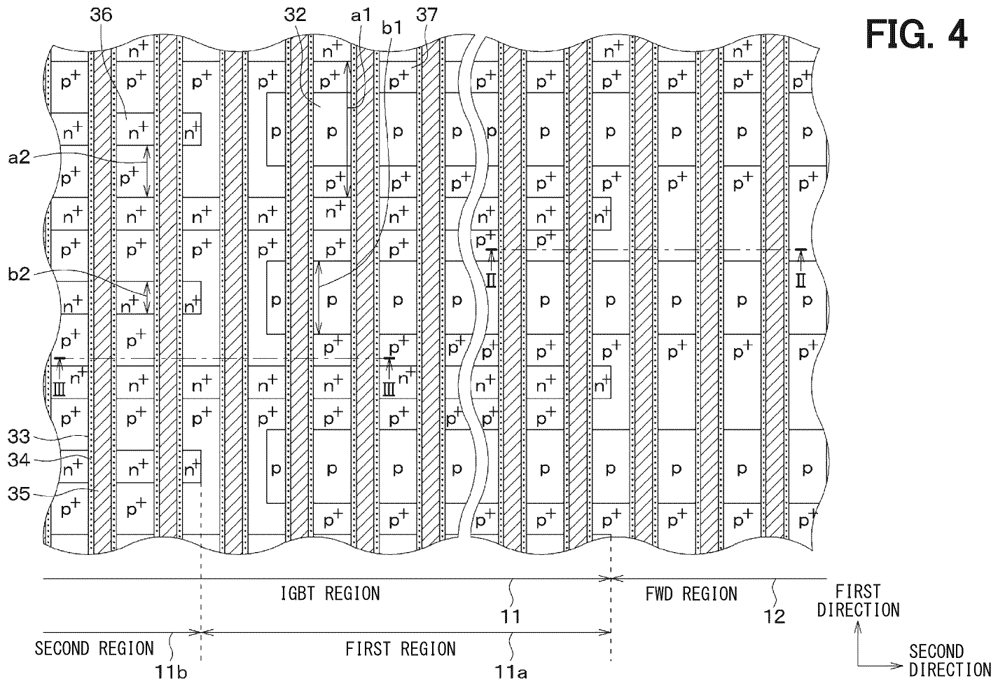

A first embodiment will be described with reference to the drawings. A semiconductor device of this embodiment is used, for example, as a power switching element in a power supply circuit such as an inverter. The semiconductor device according to the present embodiment will be described with reference to FIGS. 1 to 4. FIG. 4 is a plan view illustrating one surface 30a of a semiconductor substrate 30, which will be described later. FIG. 2 is a cross-sectional view taken along line II-II in FIG. 1 and taken along line II-II in FIG. 4. FIG. 3 is a cross-sectional view taken along line III-III in FIG. 1 and taken along line III-III in FIG. 4. Although FIG. 4 is not a cross-sectional view, a gate insulating film 34 and a gate electrode 35, which will be described later, are hatched to facilitate understanding.

As illustrated in FIG. 1, the semiconductor device includes a cell region 10, and an outer peripheral region 20 surrounding the cell region 10. Although not particularly limited, in this embodiment, two cell regions 10 are formed. Agate electrode 35 (to be described later) is formed in the cell region 10. A pad 21 is formed in the outer peripheral region 20, and connected to a temperature sensor (not shown) and the gate electrode 35.

As shown in FIGS. 1 and 2, the cell region 10 has an IGBT region 11 that functions as an IGBT element, and an FWD region 12 adjacent to the IGBT region 11 to function as an FWD element. The semiconductor device of this embodiment is an RC-IGBT in which the IGBT region 11 and the FWD region 12 are formed in a common semiconductor substrate 30, which will be described later. In this embodiment, five IGBT regions 11 and four FWD regions 12 are formed in each cell region 10. Each of the IGBT region 11 and the FWD region 12 has a rectangular shape in a plan view. The IGBT region 11 and the FWD region 12 are alternately arranged in an arrangement direction intersecting a longitudinal direction of the IGBT region 11 and the FWD region 12. In the present embodiment, the IGBT regions 11 and the FWD regions 12 are formed such that the IGBT region 11 is located at both ends in the arrangement direction. The IGBT region 11 has an area larger than the FWD region 12 in order to improve the current capability when the IGBT element is turned on.

As will be described in detail later, in this embodiment, the IGBT region 11 is located above the collector layer 41 on the other surface 30b of the semiconductor substrate 30, and the FWD region 12 is located above the cathode layer 42 on the other surface 30b of the semiconductor substrate 30. As shown in FIGS. 2 and 3, the IGBT region 11 has a first region 11a adjacent to the FWD region 12, and a second region 11b opposite to the FWD region 12 through the first region 11a. In this embodiment, the first region 11a and the FWD region 12 are formed adjacent to each other.

The semiconductor device is made of silicon or the like, and includes the semiconductor substrate 30 having the one surface 30a and the other surface 30b opposite to the one surface 30a. Specifically, the semiconductor substrate 30 has an n-type drift layer 31, and a p type base layer 32 formed on the drift layer 31. In this embodiment, the one surface 30a of the semiconductor substrate 30 is adjacent to the base layer 32, and the other surface 30b is adjacent to the collector layer 41 and the cathode layer 42.

Multiple trenches 33 are provided in the semiconductor substrate 30 to penetrate through the base layer 32 and reach the drift layer 31. Accordingly, the base layer 32 is divided into multiple pieces by the trenches 33. In the present embodiment, the trenches 33 are formed in each of the IGBT region 11 and the FWD region 12. In the present embodiment, the trenches 33 are formed in a striped shape to have a longitudinal direction (the left-right direction on the paper surface in FIG. 1) intersecting the arrangement direction of the IGBT region 11 and the FWD region 12. The distance between the two trenches 33 adjacent to each other (that is, a pitch distance) is, for example, about 2 μm. In the following description, the longitudinal direction of the trench 33 is defined as a first direction, and a second direction is perpendicular to the first direction and along the surface direction of the semiconductor substrate 30. In FIGS. 2 and 3, the depth direction on the paper surface is the first direction, and the left-right direction on the paper surface is the second direction. The second direction is the arrangement direction of the trenches 33.

Each of the trenches 33 is filled with a gate insulating film 34 formed to cover a wall surface of each trench 33, and a gate electrode 35 made of polysilicon or the like formed on the gate insulating film 34. As a result, a trench gate structure is formed. The gate electrode 35 arranged in the trench 33 of the IGBT region 11 is connected to the pad 21 formed in the outer peripheral region 20 via a gate wiring (not shown), and the pad 21 is connected to a drive circuit via a resistor (not shown) or the like. A predetermined gate voltage is applied to the gate electrode 35. The gate electrode 35 disposed in the trench 33 of the FWD region 12 is electrically connected to an upper electrode 39 (that is, an emitter), and is maintained at a predetermined potential.

As shown in FIGS. 2 to 4, an emitter region 36 and a contact region 37 are formed in a surface layer of the base layer 32 in the IGBT region 11. The emitter region 36 is an n+ type region having a higher impurity concentration than the drift layer 31, and is formed to be in contact with the trench 33. The contact region 37 is of p+ type and has a higher impurity concentration than the base layer 32.

The shapes of the emitter region 36 and the contact region 37 in the IGBT region 11 of this embodiment will be specifically described with reference to FIG. 4.

The emitter regions 36 are arranged in the first direction, between the trenches 33, in contact with the adjacent trench 33 in the second direction. In a semiconductor device having an IGBT element, when a length of the emitter region 36 in the first direction is defined as a width, the switching resistance is determined by the maximum width of the emitter region 36. Therefore, if the width of the emitter region 36 varies, this will cause variations in the switching resistance. Therefore, in this embodiment, the widths of the emitter regions 36 are made equal to each other.

In the first region 11a, the emitter region 36 is formed to be sparser than in the second region 11b. In other words, the ratio of the emitter region 36 to the one surface 30a of the first region 11a is smaller than the ratio of the emitter region 36 to the one surface 30a of the second region 11b. Hereinafter, a distance between the emitter regions 36 adjacent to each other in the first direction in the second region 11b is defined as an interval a2, and a distance between the emitter regions 36 adjacent to each other in the first direction in the first region 11a is defined as an interval a1. In this embodiment, the interval a1 is larger than the interval a2 so that the emitter region 36 is sparser in the first region 11a than in the second region 11b. That is, in the first region 11a, the number of the emitter regions 36 is smaller, compared to the second region 11b. In this embodiment, if the emitter region 36 of the first region 11a is connected to the emitter region 36 of the second region 11b in the second direction, a straight line is formed. In other words, the emitter region 36 of the first region 11a is formed on a virtual straight line that passes through the emitter region 36 of the second region 11b and extends in the second direction.

In this embodiment, the interval a1 is set to be twice the interval a2, but the ratio of the interval a2 to the interval a1 is not particularly limited. The emitter region 36 is formed by arranging a mask or the like on the one surface 30a of the semiconductor substrate 30, and then ion-implanting and diffusing n-type impurities. In this case, the processing of the mask will complicate the manufacturing process unless the emitter region 36 of the first region 11a and the emitter region 36 of the second region 11b are connected in the second direction to form a straight line, and the interval a1 is an integer multiple of the interval a2 that is two or more. For this reason, it is preferable that the interval a1 is an integer multiple of the interval a2, which is equal to or greater than 2.

The contact region 37 is formed at a position where the emitter region 36 is not formed, around the emitter region 36 to suppress latch-up. Specifically, in the second region 11b, the contact region 37 is formed such that the emitter region 36 and the contact region 37 are alternately arranged in the first direction. In the first region 11a, as described above, the number of the emitter regions 36 is reduced, compared to the second region 11b. In the portion of the first region 11a where the emitter region 36 is not formed, the base layer 32 is formed up to the one surface 30a of the semiconductor substrate 30. Therefore, in the first region 11a, the contact region 37, the emitter region 36, the contact region 37, and the base layer 32 are arranged in this order in the first direction. The base layer 32 is connected to an upper electrode 39 (described later) via a Schottky contact.

The contact region 37 is formed sparsely in the first region 11a than in the second region 11b. In other words, the ratio of the contact region 37 to the one surface 30a in the first region 11a is smaller than the ratio of the contact regions 37 to the one surface 30a in the second region 11b. Hereinafter, a distance between the contact regions 37 adjacent to each other in the first direction in the second region 11b is referred to as an interval b2, and a distance between the contact regions 37 adjacent to each other through the base layer 32 in the first direction in the first region 11a is referred to as an interval b1. The interval b2 between the contact regions 37 in the second region 11b is the width of the emitter region 36.

In this embodiment, the interval b1 is larger than the interval b2 so that the contact region 37 is sparser in the first region 11a than in the second region 11b. In other words, if the length of the contact region 37 in the first direction is defined as the width, the width of the contact region 37 in the first region 11a is narrower than the width of the contact region 37 in the second region 11b.

In this embodiment, the emitter region 36 is formed to terminate between the trenches 33 at the boundary between the first region 11a and the FWD region 12 and at the boundary between the first region 11a and the second region 11b. At this position, the contact region 37 is formed to surround the emitter region 36 to suppress latch-up.

The emitter region 36 and the contact region 37 of the IGBT region 11 are shaped in this manner in this embodiment.

In the FWD region 12, the base layer 32 constitutes an anode layer that functions as a part of the anode. In the base layer 32 of the FWD region 12, the emitter region 36 like that in the IGBT region 11 is not formed, but the contact region 37 similar to that in the first region 11a is formed. The base layer 32 is formed up to the one surface 30a of the semiconductor substrate 30 at the position between the contact regions 37 adjacent to each other in the first direction in the FWD region 12.

As shown in FIGS. 2 and 3, an interlayer insulating film 38 made of Boro Phospho Silicate Glass (BPSG) or the like is formed on the one surface 30a of the semiconductor substrate 30. The interlayer insulating film 38 has a contact holes 38a, in the first region 11a of the IGBT region 11, to expose the emitter region 36, the contact region 37, and the base layer 32. The interlayer insulating film 38 has a contact hole 38b, in the second region 11b of the IGBT region 11, to expose the emitter region 36 and the contact region 37. The interlayer insulating film 38 has a contact hole 38c, in the FWD region 12, to expose the contact region 37, the base layer 32, and the gate electrode 35.

The upper electrode 39 is formed on the interlayer insulating film 38. The upper electrode 39 is electrically connected to the emitter region 36, the contact region 37, and the base layer 32 through the contact hole 38a in the first region 11a of the IGBT region 11. The upper electrode 39 is electrically connected to the emitter region 36 and the contact region 37 through the contact hole 38b in the second region 11b of the IGBT region 11. In the FWD region 12, the upper electrode 39 is electrically connected to the contact region 37, the base layer 32, and the gate electrode 35 through the contact hole 38c. The upper electrode 39 functions as an emitter electrode in the IGBT region 11 and as an anode electrode in the FWD region 12.

The upper electrode 39 is in ohmic contact with the emitter region 36 and the contact region 37, and is in Schottky contact with the base layer 32. Therefore, in the IGBT region 11, the first region 11a has a smaller portion that is ohmic-connected than the second region 11b. In the present embodiment, the upper electrode 39 corresponds to a first electrode.

An n-type field stop layer (hereinafter, simply referred to as FS layer) 40 is formed on the drift layer 31a opposite to the base layer 32 (that is, the other surface 30b of the semiconductor substrate 30). The FS layer 40 is not necessarily needed, but is provided in order to improve characteristics of breakdown voltage and steady loss by restricting spread of a depletion layer, and control implantation amount of holes injected from the other surface 30b of the semiconductor substrate 30.

A p+ type collector layer 41 and an n+ type cathode layer 42 are formed the FS layer 40 opposite to the drift layer 31 (i.e., the other surface 30b of the semiconductor substrate 30). The IGBT region 11 and the FWD region 12 are defined depending on whether a layer formed on the other surface 30b of the semiconductor substrate 30 is the collector layer 41 or the cathode layer 42.

The lower electrode 43 is formed on the other surface 30b of the semiconductor substrate 30. The lower electrode 43 functions as a collector electrode in the IGBT region 11 and as a cathode electrode in the FWD region 12. In this embodiment, the lower electrode 43 corresponds to a second electrode.

With this configuration, an IGBT element is formed in the IGBT region 11, with the base layer 32 as a base, the emitter region 36 as an emitter, and the collector layer 41 as a collector. In the FWD region 12, a pn junction FWD element is formed with the base layer 32 and the contact region 37 serving as an anode and the drift layer 31 and the cathode layer 42 serving as a cathode.

In this embodiment, the n-type corresponds to a first conductivity type, and the p-type corresponds to a second conductivity type. Next, the operation of the semiconductor device having the IGBT element and FWD element configured as described above will be described, and the detailed configuration of the semiconductor device will be further described.

The IGBT element in the semiconductor device performs a switching operation of passing a current between the emitter and the collector and cutting off the current by controlling the gate voltage applied to the gate electrode 35. That is, the IGBT element is switched between an on state and an off state by controlling the gate voltage applied to the gate electrode 35. Furthermore, the FWD element in the semiconductor device operates as a diode in conjunction with the switching operation of the IGBT element, thereby suppressing the occurrence of surges during switching.

At this time, in the semiconductor device of this embodiment, the contact region 37 in the first region 11a is formed sparsely than the contact region 37 in the second region 11b. Therefore, compared to a case where the IGBT region 11 is formed only of the second region 11b, the amount of holes injected from the contact region 37 of the IGBT region 11 toward the cathode layer 42 can be reduced during recovery when the IGBT element is switched from the off state to the on state. Therefore, it is possible to suppress an increase in the tail current caused by an increase in carrier density adjacent to the cathode layer 42, so as to reduce the recovery loss Err.

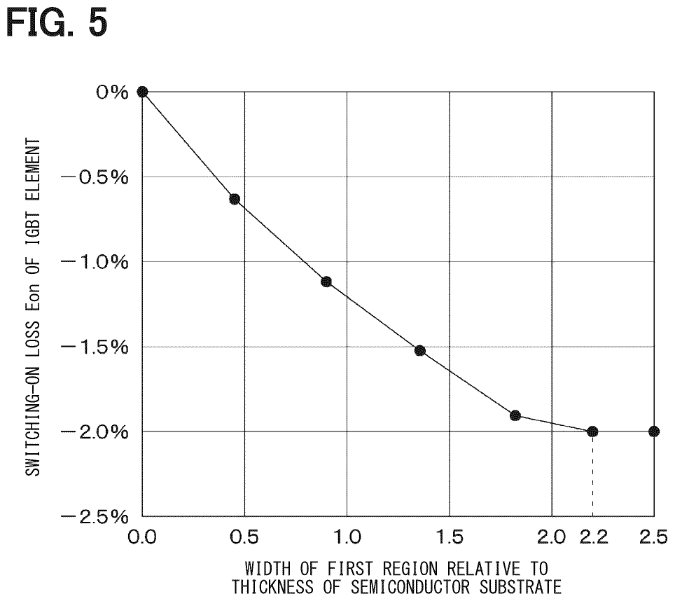

Since the switching-on loss Eon of the IGBT element depends on the recovery loss Err, the switching-on loss Eon can be reduced by widening the first region 11a in which the contact region 37 is sparsely formed. For this reason, the inventors have conducted extensive research into the length of the first region 11a in the second direction (hereinafter also referred to as the width of the first region 11a), and have obtained the results shown in FIG. 5. The length in the left-right direction of the paper surface of FIGS. 2 and 3 is the width of the first region 11a. FIG. 5 shows the switching-on loss Eon when the IGBT region 11 is formed only of the second region 11b as 0% (i.e., reference).

As shown in FIG. 5, it is confirmed that the switching-on loss Eon of the IGBT element can be reduced by increasing the width of the first region 11a. However, it is confirmed that the switching-on loss Eon does not change when the width of the first region 11a becomes 2.2 times or more the thickness of the semiconductor substrate 30. As described later, as the width of the first region 11a is increased, the area where the current density is low increases, and therefore the maximum current density increases. Therefore, it is preferable that the first region 11a be located within 2.2 times the thickness of the semiconductor substrate 30 from the end of the FWD region 12. In other words, a region where the contact region 37 is sparser than the second region 11b, including the first region 11a, is preferably within 2.2 times the thickness of the semiconductor substrate 30 from the end of the FWD region 12. Therefore, in this embodiment, the first region 11a is set to be within 2.2 times the thickness of the semiconductor substrate 30 from the end of the FWD region 12. In this embodiment, the end of the FWD region 12 is the boundary between the FWD region 12 and the first region 11a.

The first region 11a is an IGBT element in which the emitter region 36 is formed. Therefore, in the semiconductor device of this embodiment, the current capability can be improved compared to a case where a boundary region in which the emitter region 36 is not formed is arranged instead of the first region 11a.

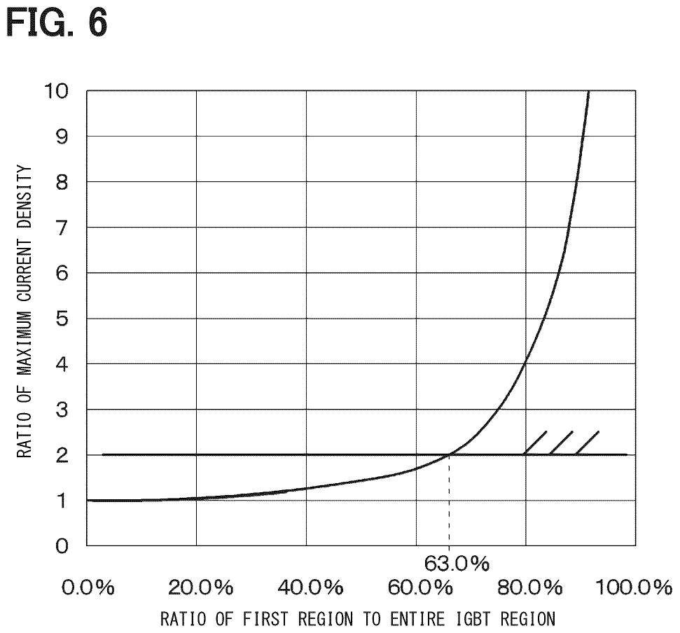

However, the first region 11a is formed so that the emitter region 36 is sparser than that of the second region 11b, and the current density is lower in the first region 11a than in the second region 11b. Therefore, as the width of the first region 11a is increased, the width of the second region 11b is decreased, and the maximum current density of the IGBT region 11 increases. According to the study by the present inventors, when the interval a1 is set to twice the interval a2, the results shown in FIG. 6 are obtained. In FIG. 6, the maximum current density in the IGBT region 11 is set to 1 when the IGBT region 11 is formed only of the second region 11b.

As shown in FIG. 6, the maximum current density increases as the ratio of the first region 11a to the entire IGBT region 11 increases. At present, taking into consideration short circuit resistance and the like, it is considered preferable to make the maximum current density no more than twice as high as compared to the case where the IGBT region 11 is formed only of the second region 11b. Therefore, the ratio of the first region 11a to the IGBT region 11 is preferably 63.0% or less. In this embodiment, the ratio of the first region 11a to the IGBT region 11 is 63.0% or less.

According to the present embodiment, the region from the end of the FWD region 12, including the first region 11a, where the contact region 37 is sparser than the second region 11b is dimensioned within 2.2 times the thickness of the semiconductor substrate 30. The first region 11a has the emitter region 36 formed therein, and also functions as an IGBT element. Therefore, in the semiconductor device of this embodiment, the recovery loss Err and the switching-on loss Eon can be reduced, while restricting the maximum current density from becoming higher than when the first region 11a is a boundary region in which the emitter region 36 is not formed. Therefore, in the semiconductor device of the present embodiment, it is possible to suppress a decrease in short-circuit withstand capability while reducing the recovery loss Err and the switching-on loss Eon.
(1) In this embodiment, the first region 11a and the FWD region 12 are formed adjacent to each other. That is, the end of the FWD region 12 is the boundary between the first region 11a and the FWD region 12. Therefore, the current capability can be improved compared to a case where a boundary region is formed, where no emitter region 36 is formed, between the FWD region 12 and the first region 11a. Therefore, the maximum current density can be further restricted from becoming high.
(2) In this embodiment, the widths of the emitter regions 36 in the first direction are made the same. This makes it possible to suppress variations in switching resistance.
(3) In the present embodiment, the first region 11a occupies 63.0% or less of the entire IGBT region 11. Therefore, the maximum current density can be reduced to less than twice that in case where the IGBT region 11 is formed only of the second region 11b, thereby meeting current requirements.
(4) In the present embodiment, the interval a1 is an integer multiple of the interval a2, which is equal to or greater than two, and the emitter region 36 of the first region 11a is formed to be positioned on a virtual straight line that passes through the emitter region 36 of the second region 11b and extends along the second direction. This makes it possible to restrict the processing of the mask when forming the emitter region 36 from becoming complicated, and thus makes it possible to restrict an increase in the number of manufacturing steps.

### OTHER EMBODIMENTS

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

In the first embodiment, the widths of the emitter regions 36 may not be the same. In the first embodiment, the first region 11a may occupy 63.0% or more of the entire IGBT region 11. In the first embodiment, the interval a1 may not be an integer multiple of the interval a2. Even with these configurations, the region from the end of the FWD region 12 where the contact region 37 is sparser than the second region 11b, including the first region 11a, is set to be within 2.2 times the thickness of the semiconductor substrate 30, thereby restricting a decrease in the short-circuit resistance, as in the first embodiment.

In the first embodiment, the first conductivity type is n-type and the second conductivity type is p-type. Alternatively, the first conductivity type may be p-type and the second conductivity type may be n-type.

In the first embodiment, the number of the cell regions 10 may be one or three or more. The number of the IGBT regions 11 and the FWD regions 12 formed in each cell region 10 can be changed as appropriate.

In the first embodiment, the boundary between the first region 11a and the second region 11b may coincide with the trench 33. That is, the emitter region 36 in the second region 11b closest to the first region 11a may be formed in contact with the trench 33 rather than terminating between the trenches 33. Similarly, the emitter region 36 in the first region 11a closest to the FWD region 12 may be formed in contact with the trench 33 instead of terminating between the trenches 33.

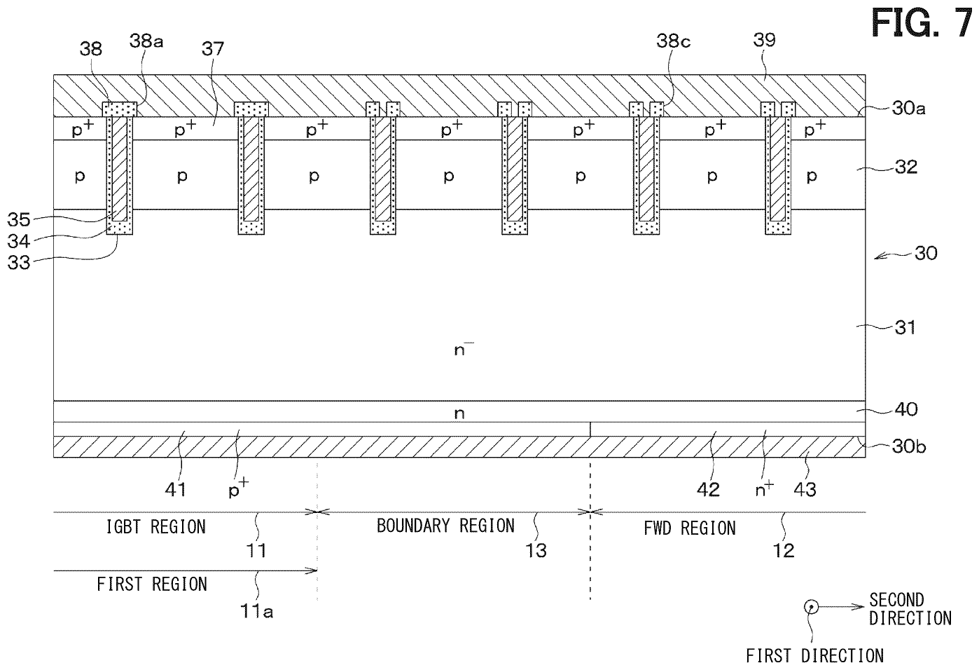

In the first embodiment, as shown in FIG. 7, a boundary region 13 in which no emitter region 36 is formed may be formed between the first region 11a and the FWD region 12. In other words, a portion of the first region 11a adjacent to the FWD region 12 in the first embodiment may be the boundary region 13. Even with this configuration, the region from the end of the FWD region 12 where the contact region 37 is sparser than the second region 11b, including the first region 11a, is within 2.2 times the thickness of the semiconductor substrate 30. This region includes the first region 11a. Therefore, the recovery loss Err and the switching-on loss Eon can be reduced, and the reduction in the short-circuit withstand capability can be suppressed.

What is claimed is:

1. A semiconductor device comprising:
a semiconductor substrate in which an IGBT region having an IGBT element and an FWD region having an FWD element are formed, wherein the semiconductor substrate includes a drift layer of a first conductivity type, a base layer of a second conductivity type formed on the drift layer, a collector layer of a second conductivity type formed opposite to the base layer through the drift layer in the IGBT region, and a cathode layer of a first conductivity type formed opposite to the base layer through the drift layer in the FWD region, the semiconductor substrate having one surface adjacent to the base layer and the other surface adjacent to the collector layer and cathode layer;
a plurality of trench gate structures formed in the IGBT region to have a gate insulating film on a wall surface of a trench and a gate electrode formed on the gate insulating film, the trench penetrating the base layer to reach the drift layer and extending in a surface direction of the semiconductor substrate as a longitudinal direction;
an emitter region of a first conductivity type formed in a surface layer of the base layer in the IGBT region to be in contact with the trench;
a contact region of a second conductivity type formed in a surface layer of the base layer in the IGBT region, different from the emitter region, to have a higher impurity concentration than the base layer;
a first electrode disposed on the one surface of the semiconductor substrate and electrically connected to the emitter region and the contact region; and
a second electrode disposed on the other surface of the semiconductor substrate and electrically connected to the collector layer and the cathode layer, wherein
the IGBT region has a first region located adjacent to the FWD region and a second region located opposite to the FWD region through the first region,
the first region is formed in a state where the emitter region is sparser than the second region, and where the contact region is sparser than the second region, and
a region from an end of the FWD region adjacent to the IGBT region, including the first region, where the contact region is sparser than the second region is dimensioned within 2.2 times a thickness of the semiconductor substrate.

2. The semiconductor device according to claim 1, wherein the end of the FWD region adjacent to the IGBT region is a boundary between the first region and the FWD region.

3. The semiconductor device according to claim 1, wherein
the emitter region is one of a plurality of emitter regions arranged in the longitudinal direction of the trench, and
widths of the emitter regions are equal to each other in the longitudinal direction of the trench.

4. The semiconductor device according to claim 1, wherein a ratio of the first region with respect to an entirety of the IGBT region is less than or equal to 63.0%.

5. The semiconductor device according to claim 1, wherein
the emitter region is one of a plurality of emitter regions arranged in the longitudinal direction of the trench,
an interval of the emitter regions in the first region in the longitudinal direction of the trench is set to an integer multiple of 2 or more with respect to an interval of the emitter regions in the second region in the longitudinal direction of the trench,
the trench is one of a plurality of trenches, and
the emitter region of the first region is formed on a virtual straight line that passes through the emitter region of the second region and extends in an arrangement direction of the plurality of trenches.

6. The semiconductor device according to claim 1, wherein
a width of the contact region in the longitudinal direction of the trench in the second region is larger than that in the first region and smaller than twice of that in the first region.
